(19) United States
(12) Patent Application Publication
(10) Pub. No.: US 2025/0199104 A1
(43) Pub. Date: Jun. 19, 2025

(54) MONITORING TECHNOLOGIES FOR MRI COILS AND ARRAYS

(71) Applicant: NORTECH SYSTEMS, INC., Maple Grove, MN (US)

(72) Inventors: Carl SNYDER, Bloomington, MN (US); Jay D. MILLER, Minneapolis, MN (US); Brandon Lee MAGNAN, Crystal, MN (US)

(73) Assignee: NORTECH SYSTEMS, INC., Maple Grove, MN (US)

(21) Appl. No.: 18/846,121

(22) PCT Filed: Mar. 6, 2023
(86) PCT No.: PCT/US2023/063764

§ 371 Date: Sep. 11, 2024

Related U.S. Application Data
(60) Provisional application No. 63/318,865, filed on Mar. 11, 2022.

(51) Int. Cl. G01R 35/00; G01R 33/34; G01R 33/36; G08B 21/18

(52) U.S. Cl. CPC G01R 35/00; G01R 33/34015; G01R 33/3642; G08B 21/182

(57) ABSTRACT

An MRI coil testing system includes a frequency response monitoring subsystem and a temperature monitoring subsystem. The frequency response monitoring subsystem includes an embedded receiver probe configured to measure each individual coil's resonant frequency and nng-up/ring-down time, and a processor configured to output an alert if the resonant frequency or ring-up/ring-down time exceeds or violates respective thresholds. The temperature monitoring subsystem includes an embedded temperature probe configured to monitor the temperature of individual coils and the temperature of a magnetic resonance/radio frequency connector, and a processor configured to output an alert if either temperature exceeds a threshold.

### RELATED APPLICATIONS

This application claims the benefit of U.S. Provisional Application No. 63/318,865, filed Mar. 11, 2022, which is hereby incorporated herein by reference in its entirety.

### TECHNICAL FIELD

The disclosed implementations relate generally to testing magnetic resonance imaging (MRI) coils in MRI systems, and specifically to testing the resonant frequency of the MRI coils, the detuning circuit of MRI systems, the inductive coupling between coils within coil arrays, the temperature of individual coils and array cables of MRI systems.

### BACKGROUND

Currently there is no way to test the signal integrity of an MRI coil or array of MRI coils outside of the MRI system. Testing an MRI coil may be useful to predict coil failure, or to know in advance whether the system in which the MRI coil is deployed will produce high quality images that are useful for clinical diagnoses. Without testing, there is no way for personnel in radiology departments or imaging centers to know if an MRI coil or array is broken, until a patient is in the magnet, during a clinical scan, and the MRI system returns a substandard image. This poses significant risk that the scan is not of diagnostic quality, or worse, cause harm to the patient through RF burning.

In addition, there are very few ways to quantitatively determine if a receiver coil or array is working correctly (especially in high coil count arrays) for an MRI system in a clinical setting. More importantly, there are no methods that continuously monitor the health of an MRI coil or array during an imaging scan. If a single coil or cable within an array is not working correctly, it poses significant risk; the image may not be of diagnostic quality, or worse, cause harm to the patient through RF or thermal burning.

### SUMMARY

Accordingly, there is a need for a fixture that can test MRI coils or an array of MRI coils. This fixture may be used outside of the magnet room prior to patient scanning. Implementations of a fixture as described herein can test the integrity of the MRI coil or array of MRI coils by checking each individual coil's resonant frequency, checking each individual coil's rise/ringdown time, and checking the inductive coupling between coils within an array. For more robust statistical analysis, e.g., to predict future coil failures more accurately, the fixture may send coil data to a cloud database where it can be analyzed and aggregated with data from other coils, which can be used to predict, e.g., with artificial intelligence, how long an MRI coil has before it breaks.

In addition, there is a need for an integrated system that can determine the health and safety of a receiver coil or array in an MRI system by continuously monitoring the MRI coil or array throughout a patient scan. Implementations of an integrated system as described herein can test, during clinical use of an MRI system, the integrity of the MRI coil or array of MRI coils by checking each individual coil's resonant frequency, checking each individual coil's rise/ringdown time, and checking the temperature of each individual coil within the array as well as the temperature of the array cable attached to a table mounted connector. If an MRI coil's resonant frequency is too far from the known Larmor frequency, the ring-up or ring-down time is too long, or the temperature of the MRI coil or cable is too high, the system outputs a warning.

### BRIEF DESCRIPTION OF THE DRAWINGS

For a better understanding of the various described implementations, reference should be made to the Detailed Description below, in conjunction with the following drawings in which like reference numerals refer to corresponding parts throughout the Figures.

FIG. 1 is a block diagram of an MRI coil testing system in accordance with some implementations.

FIG. 2 is a block diagram of a transmit unit of the MRI coil testing system of FIG. 1, in accordance with some implementations.

FIG. 3 is a block diagram of a receive unit of the MRI coil testing system of FIG. 1, in accordance with some implementations.

FIG. 4 is a schematic of a system coupled to an array of MRI coils, in accordance with some implementations.

FIG. 5 is a schematic of an alternate system coupled to an array of MRI coils, in accordance with some implementations.

FIG. 6 is a schematic of an alternate system coupled to an array of MRI coils, in accordance with some implementations.

FIG. 7 is a schematic of an alternative MRI coil system in accordance with some implementations.

FIG. 8 is a block diagram of an MRI coil testing system in accordance with some implementations.

FIG. 9 is a block diagram of a receive unit of the MRI coil testing system of FIG. 8, in accordance with some implementations.

FIG. 10 is a schematic of a system coupled to an array of MRI coils, in accordance with some implementations.

FIG. 11 is a schematic of an alternate system coupled to an array of MRI coils, in accordance with some implementations.

FIG. 12 is a schematic of an alternate system coupled to an array of MRI coils, in accordance with some implementations.

FIG. 13 is a schematic of an alternative MRI coil system in accordance with some implementations.

FIG. 14 is a schematic of a temperature probe arrangement with separate processors in accordance with some implementations.

FIG. 15 is a schematic of a temperature probe arrangement with a single processor in accordance with some implementations.

FIG. 16 is a schematic of a temperature probe arrangement in a cable in accordance with some implementations.

FIG. 17 is a schematic of an alternative MRI coil system with additional processors in accordance with some implementations.

### DETAILED DESCRIPTION

Reference will now be made in detail to implementations, examples of which are illustrated in the accompanying drawings. In the following detailed description, numerous specific details are set forth in order to provide a thorough understanding of the various described implementations. However, it will be apparent to one of ordinary skill in the art that the various described implementations may be practiced without these specific details. In other instances, well-known methods, procedures, components, circuits, and networks have not been described in detail so as not to unnecessarily obscure aspects of the implementations.

It will also be understood that, although the terms “first,” “second,” etc. are, in some instances, used herein to describe various elements, these elements should not be limited by these terms. These terms are only used to distinguish one element from another. For example, a first electronic device could be termed a second electronic device, and, similarly, a second electronic device could be termed a first electronic device, without departing from the scope of the various described implementations. The first electronic device and the second electronic device are both electronic devices, but they are not necessarily the same electronic device.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

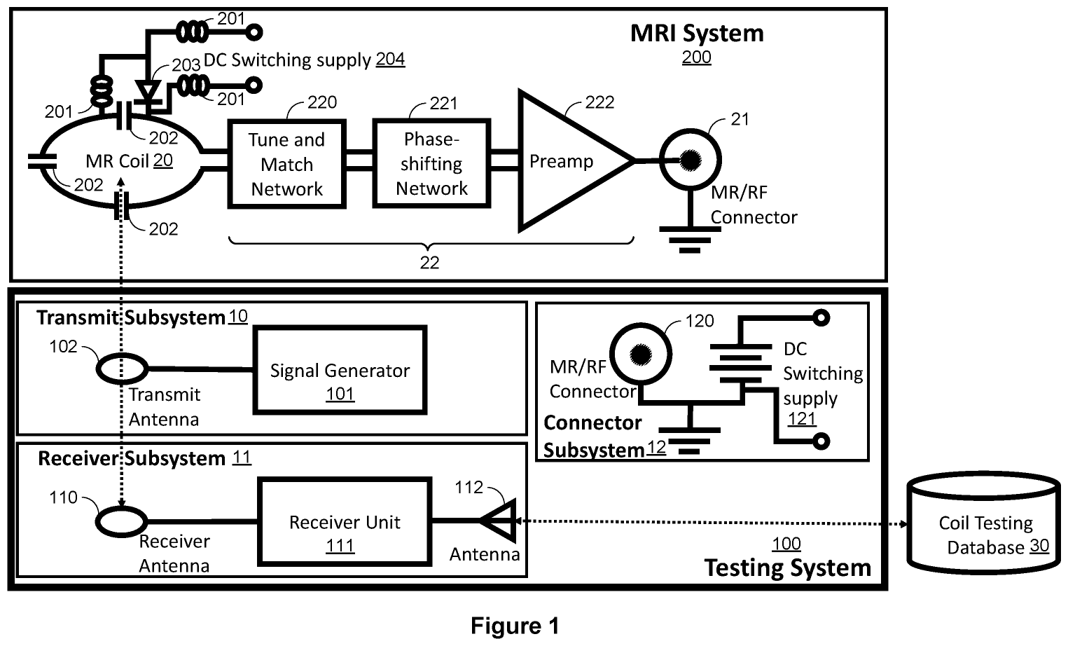

Turning now to FIG. 1, a block diagram of an overview of the testing system 100, in accordance with one aspect of the disclosure, is shown. Testing system 100 includes a transmit subsystem 10, a receiver subsystem 11, and a connector subsystem 12. An MRI system 2 is operatively (physically and/or communicatively) coupled to transmit subsystem 10, receiver subsystem 11, and connector subsystem 12. In some aspects, MRI system 2 is separately operatively coupled to transmit subsystem 10, receiver subsystem 11 and connector subsystem 12. MRI system 2 contains an MRI coil 20, which may be coupled to other electronic components (e.g., inductors 201, capacitors 202, and a diode 203), the specifics of which are outside the scope of this disclosure.

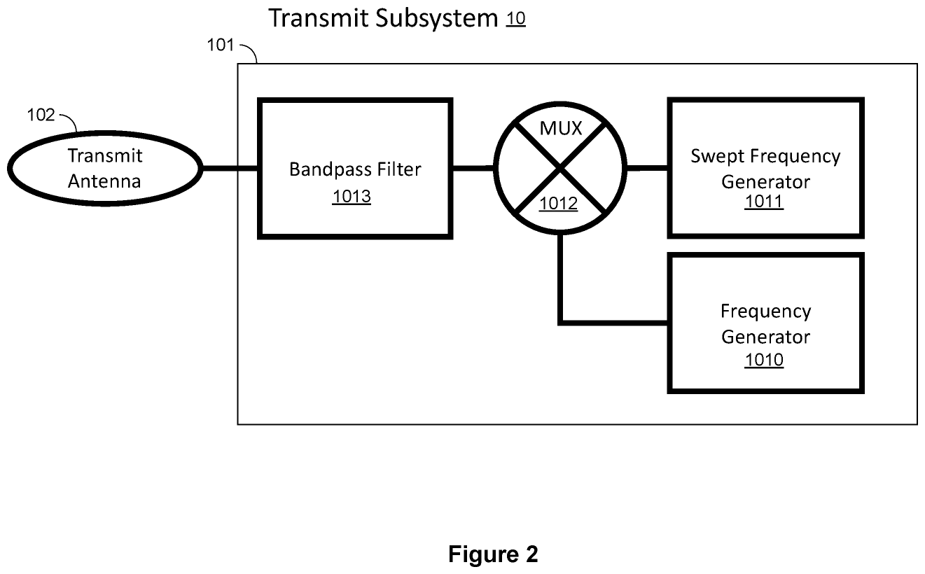

Transmit subsystem 10 may contain a transmit antenna 102 and a signal generator 101. In one embodiment, as shown in FIG. 2, the signal generator 101 of transmit subsystem 10 may also include frequency generator 1010 and swept frequency generator 1011, which are both fed into multiplexor 1012. The output of multiplexor 1012 is fed to bandpass filter 1013, which is then transmitted by transmit antenna 102.

Returning to FIG. 1, transmit antenna 102 may be communicatively and/or physically coupled to MRI coil 20 (e.g., coupled to a capacitor 202 of MRI coil 20), to facilitate testing of MRI coil 20. To properly perform MRI diagnostic tests and produce clinically useful images, coil 20 is designed to resonate at a resonant frequency referred to as the Larmor frequency. However, over time and use, coil 20 may become out of tune and may instead resonate at a different frequency, which would cause it to be unable to produce appropriate quality images. To test the resonant frequency of MRI coil 20, signal generator 101 may be configured to generate a plurality of transmit signals at a plurality of transmit signal frequencies within a transmit frequency band close to the Larmor Frequency. In some aspects, frequency generator 1010 and swept frequency generator 1011 may both generate signals, which are multiplexed up to the Larmor frequency or the other adjacent testing frequencies by multiplexor 1012 and then filtered by bandpass filter 1013. Once each signal is ready, the transmit antenna 102 may transmit the signal to MRI coil 20 via the coupling of transmit antenna 102 to capacitor 202 of MRI coil 20. Coil 20 will then absorb energy from each of the signals transmitted by transmit antenna 102 and generate a frequency response. In alternative implementations, one or more of bandpass filter 1013, multiplexor 1012, frequency generator 1010, and swept frequency generator 1011 may be removed from transmit subsystem 10. In general, the components of transmit subsystem 10 are just one example implementation among many; components may be removed, added, and/or substituted as long as the transmit subsystem 10 is configured to transmit signals as described herein.

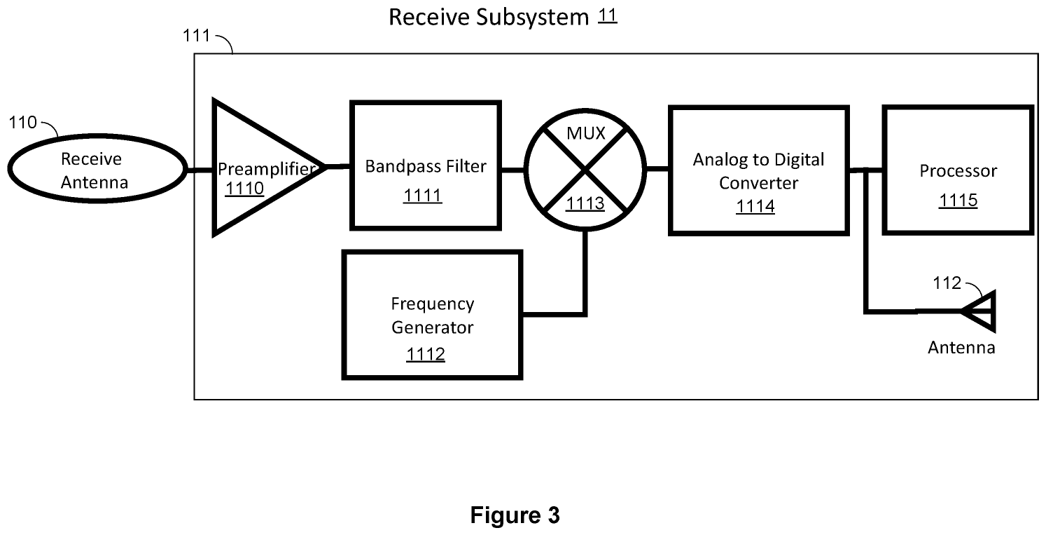

Receive subsystem 11 may contain a receiver antenna 110, a receiver unit 111 and an external antenna 112. As shown in FIG. 3, receiver unit 111 may include a preamplifier 1110, a bandpass filter 1111, a frequency generator 1112, a multiplexor 1113, an analog to digital converter 1114 and a processor 1115. Analog to digital converter 1114 and processor 1115 may be operatively coupled to external antenna 112. Turning back to FIG. 1, receiver antenna 110 may also be communicatively and/or physically coupled to MRI coil 20 (e.g., coupled to capacitor 202 of MRI coil 20). However, in one aspect of the disclosure, transmit antenna 102 and receiver antenna 110 are both coupled to capacitor 202 of MRI coil 20 but are not coupled to each other. In alternative implementations, one or more of preamplifier 1110, bandpass filter 1111, frequency generator 1112, multiplexor 1113, analog to digital converter 1114, and processor 1115 may be removed from receive subsystem 11. In general, the components of receive subsystem 11 are just one example implementation among many; components may be removed, added, and/or substituted as long as the receive subsystem 11 is configured to transmit signals as described herein.

To test the MRI coil's resonance, transmitter subsystem 11 generates a signal that sweeps across a frequency band close to (e.g., within 50% of) and on the Larmor frequency. The signal is broadcasted by the transmit antenna 112 which is also coupled to the MRI coil 20. The receiver antenna 110, which is also coupled to the MRI coil 20, receives the amplitude of the MRI coil's frequency response. As the transmit frequency gets closer to the Larmor frequency, the amplitude of the signal received at the receiver antenna 110 should also increase. If the received signal (received at receiver antenna 110) is not maximum at the Larmor frequency, then the MRI coil 20 is not resonant (not resonant as designed or otherwise intended), and is therefore broken.

More specifically, after transmit antenna 102 transmits the plurality of signals to MRI coil 20, and coil 20 generates a frequency response for each of the plurality of signals, receive antenna 110 receives each frequency response, which may include an inductive voltage. Receive antenna 110 then sends the received frequency response signal to the receiver unit 111, which puts the signal through preamplifier 1110 and then through bandpass filter 1111. Multiplexor 1113 and frequency generator 1112 may then multiplex the received signal to a lower frequency. The lower frequency signal is then converted to digital data by analog to digital converter 1114, and the digital data is sent to processor 1115, which analyzes the signal data to determine whether the frequency response signal with the highest amplitude is the frequency response signal that corresponds to the transmit signal whose frequency was the Larmor frequency. Processor 1115 may be configured to provide immediate feedback to the end user, and may also be configured to transmit the received frequency response signal data to external antenna 112. External antenna 112 may be external to the system or it may be internal to the system, but it is configured to transmit the data externally. In one aspect, external antenna 112 will send the received signal to a cloud-based server 3 that contains coil testing database 30. Server 3 may then perform more complex statistical algorithms, which may include artificial intelligence (AI), which may analyze the data, informed by data from other MRI coils, to provide predictive trends for future coil failure.

MRI systems such as MRI system 2 may contain receive-only coils and arrays, which need to be detuned or not resonant while the body coil is transmitting. This is traditionally done by adding a PIN diode, although some MRI systems may use MEMS or other switches, and an inductor into the MRI coil circuit. When the MRI coil is transmitting during an imaging task, the PIN diode is energized, which creates an LC band reject filter at the Larmor frequency that prevents the MRI coil from resonating at the Larmor frequency. However, over time the I region of a PIN diode and MEMS switches may degrade.

In some implementations, receive-only coils (e.g., coil 20) and coil arrays may need to be detuned (not resonant) while the body coil is transmitting. This may be done by adding a PIN diode (other methods may use MEMS or other switches) and inductor into the MRI coil circuitry. During transmit, the PIN diode is energized, which creates an LC band reject filter at the Larmor frequency. This prevents the MRI coil from resonating at the Larmor frequency. However, over time the I region of the PIN diode and MEMS switches start degrading. In some implementations, to test the detuning circuit, the transmitter in the test fixture continuously transmits a signal at the Larmor frequency while the DC switching supply rapidly switches+/−10 VDC (or between any other voltage rails greater than or less than 10 VDC), through the connector, to the PIN diode or MEMS switch. The DC supply tunes and detunes the MRI coil 20 on and off of the Larmor frequency. The receiver on the test fixture measures the amplitude of the receiver coil in the time domain. If the MRI coil 20 does not tune and detune fast enough, the MRI coil is broken. In some implementations, the receiver sends the amplitude data to a cloud-based database for additional analysis.

More specifically, testing system 100 may be used to test the detuning circuit of an MRI system, using receiver subsystem 11 and connector subsystem 12. Connector subsystem 12 may include a magnetic resonance/radio frequency (MR/RF) connector 120 and a direct current (DC) switching supply 121. Connector 120 may be designed to be coupled to an MR/RF connector 21 of MRI system 2, and DC switching supply 121 connectors may be designed to be coupled to DC switching supply 204 connectors. MRI system 2 may also contain a detuning circuit 22 which may include a tune and match network 220, a phase shifting network 221, and a preamplifier 222.

To test a detuning circuit such as detuning circuit 22, the transmit subsystem continuously transmits a signal at the Larmor frequency while the DC switching supply is rapidly switched between positive and negative voltage rails (e.g., +/−10 VDC, or any other voltage rails greater than or less than 10 VDC). Diode 203 may be a PIN diode. In other MRI systems, the functions of diode 203 may be performed instead by a MEMS switch. The switching of DC switching supply 204 of MRI coil 20 causes the MRI to tune and detune while the transmit subsystem is transmitting the signal at the Larmor frequency. As above, receive antenna 110 then sends the received signal to receiver unit 111, which puts the signal through preamplifier 1110 and then through bandpass filter 1111. Multiplexor 1113 and frequency generator 1112 may then multiplex the received signal to a lower frequency. The lower frequency signal is then converted to digital data by analog to digital converter 1114, and the digital data is sent to processor 1115. Receiver subsystem 11 measures the amplitude of the received response signal in the time domain, which signals how quickly the coil tunes and detunes. If coil 20 does not tune and detune fast enough (the amplitude does not rise and fall faster than a threshold), coil 20 or detuning circuit 22 may be broken. Receiver unit 111 may then send the data to cloud-based server 3 for additional analysis, which may include predictive failure analysis for detuning circuit 22 or coil 20, which may be based on data from similar coils or detuning circuits, including which rise and fall numbers predict failure, and how soon.

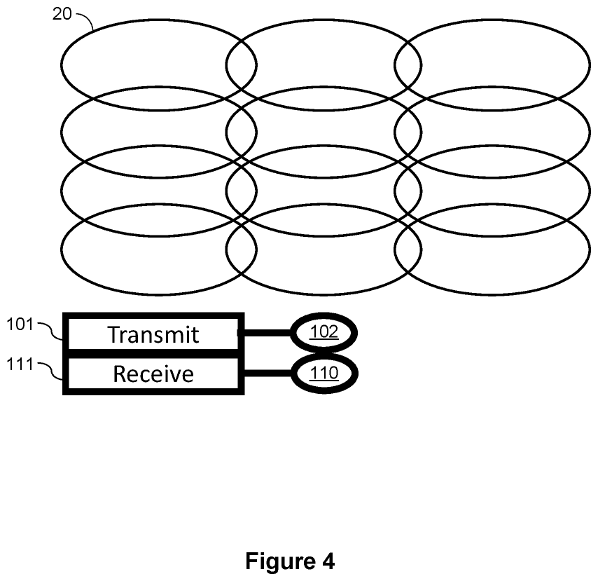

Turning now to FIGS. 4, 5, 6, 7A and 7B, block diagrams of the present disclosure, as deployed in an MRI system 2 with an array of MRI coils 20 are shown. Array coil systems may be used in MRI applications, because an individual coil may not provide enough coverage of the anatomy of the patient being scanned. By combining multiple small coils into large arrays, it is possible to obtain a high signal to noise ratio of a small cable and a large field of view. In some MRI systems, an array of MRI coils may be a switchable array, wherein different individual coils, or different sub-arrays, could be switched on and off to scan different areas of the patient's body. In some MRI system, an array of MRI coils may be a phased array. In some MRI systems, an array of MRI coils may be a parallel array. Some coil arrays may be divided into segments and/or into channels.

A testing system in accordance with FIG. 1 may be useful in an MRI system featuring an array of MRI coils, to diagnose the resonant frequency of individual coils in the array or to diagnose a detuning circuit to ensure that coils rise and fall within acceptable time intervals. FIG. 4 shows an array of twelve coils 20 within a single MRI system 2. Testing system 100 as shown in FIG. 4 may have a single transmit subsystem 10 and a single receive subsystem 11. The single transmit subsystem 10 may have a single transmit antenna 102 and a single signal generator 101. The single transmit antenna may be operatively coupled to all twelve of the MRI coils 20, and may be configured to direct a signal generated by the signal generator 101 to any of the MRI coils 20. Receive subsystem 11 may contain a single receive antenna 110 and a single receiver unit 111. Receive antenna 110 may receive frequency responses as described above, for each of the 12 coils 20 in the array of MRI coils. Because it is coupled to the twelve coils, receiver subsystem 11 in FIG. 4 may be able to identify which of the twelve coils is generating a frequency response signal, so that it is able to accurately create and analyze data relating to which coil 20 of the array may be diagnosed as failing or predicted to fail. Persons having skill in the art will recognize that an array need not be limited to twelve coils 20, and can be more or fewer coils 20. Persons having skill in the art will realize that different arrangements of MRI coils 20 in an array may be used, and that the arrangement shown is exemplary only.

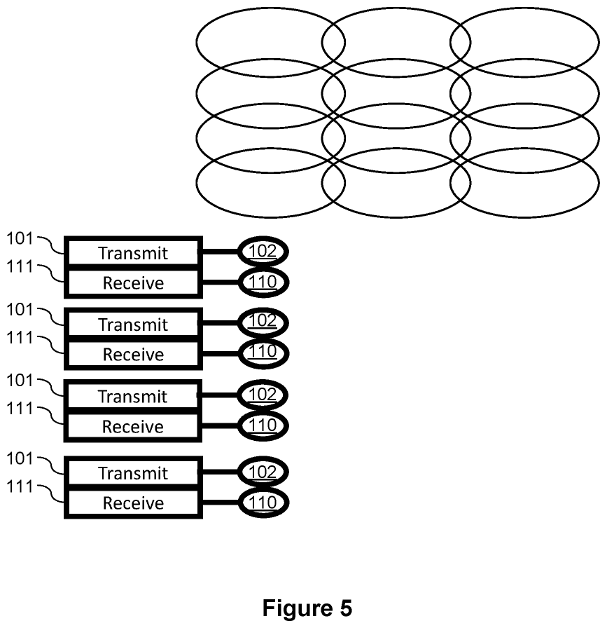

Turning now to FIG. 5, an alternate arrangement, to that of FIG. 4, for use with arrays, is shown. In FIG. 5, a twelve-coil array of MRI coils 20 is shown, similar to the array of FIG. 4. However, in FIG. 5, there are four transmit subsystems 10, consisting of four transmit antennas 102 and four signal generators 101. Also shown in FIG. 5 are four receive subsystems 11, consisting of four receive antennas 110 and four receiver units 111. In FIG. 5, the transmit subsystems 10 and receive subsystems 11 may be configured such that each one of transmit subsystem 10 and each receive subsystem 11 may be coupled to a segment or channel of MRI coils 20 or some other subset of the array. For example, each transmit subsystem 10 and each receive subsystem 11 may be coupled to three coils 20, such that a set of four transmit subsystems 10 and four receive subsystems 11 can test twelve coils 20. However, persons having skill in the art will realize that the ratio of transmit subsystems 10 and receiver subsystems 11 to MRI coils 20 need not be 1:3 or any specific ratio, and that different transmit subsystems 10 and receiver subsystems 11 in the same testing system 100 may be coupled to different numbers of MRI coils 20 as compared to other transmit subsystems 10 or receiver subsystems 11 in the same testing system 100.

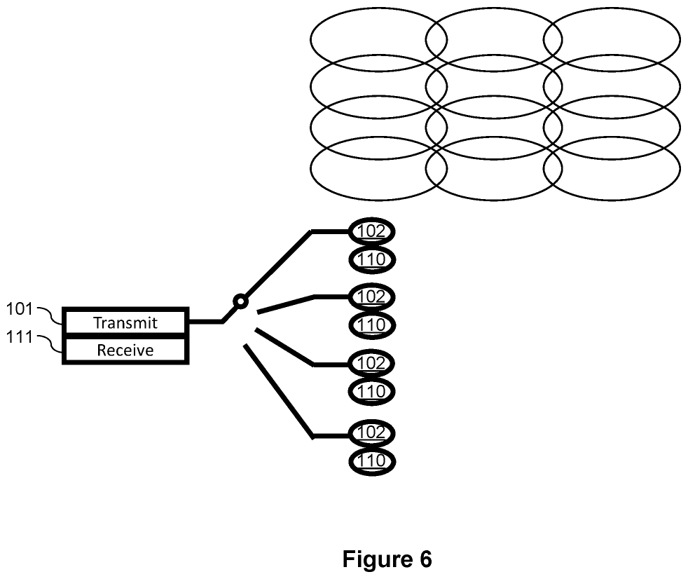

Turning now to FIG. 6, an alternate arrangement to that of FIGS. 4 and 5 is shown with respect to an array of twelve coils 20. As shown in FIG. 6, there is one signal generator 101 and one receiver unit 111. However, there are shown four transmit antennas 102 and four receive antennas 110. In the arrangement of FIG. 6, switch 13 allows a single signal generator 101 to switch between being coupled to each of the four transmit antennas 102. Switch 13 also allows a single receiver unit 111 to switch between being coupled to each of the four receive antennas 110. This way, each of the antennas can be coupled to fewer of the MRI coils 20 of the array, but the amount of circuitry for signal generator 101 and receiver unit 111 can be minimized. Persons having skill in the art will realize, as with respect to FIGS. 4 and 5, in FIG. 6 the ratio of antennas 102 and 110 to MRI coil 20 need not be 1:3 or any specific ratio. Persons having skill in the art will realize that the switched configuration of FIG. 6 is not limited to one single signal generator 101 and one single receiver unit 111, and that multiple signal generator 101 may exist in a system where there are more transmit antennas 102 than there are signal generators 101, without the specific ratio being 1:4 as shown in FIG. 6.

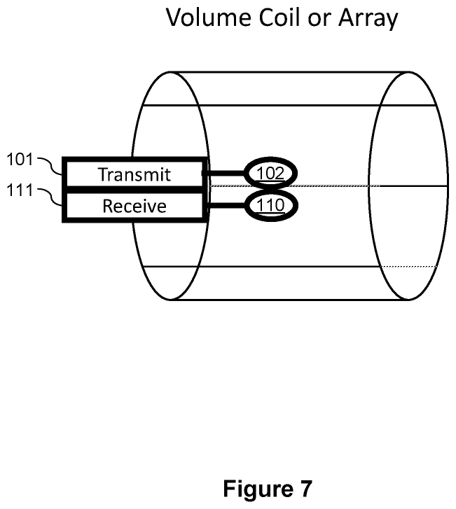

FIGS. 4 through 6 show a planar array of twelve coils 20, which has the MRI coils in the array in a single plane. Persons having skill in the art will realize that testing system 100 may also be deployed in a volume coil array, which are used in MRI tube systems that surround patients, e.g. in a cylindrical shape, while they are being imaged. A schematic of the testing system 100 as deployed in a volume coil array is shown in FIG. 7.

In some implementations, the test fixture tests inductive coupling between MRI coils within an array of MRI coils. Inductive coupling between receiver coils significantly reduces the signal to noise ratio in an image. To test the inductive coupling between MRI coils within an array, the test fixture energizes all coils and their preamps (e.g., by applying a DC voltage) and collects noise-only data. Neither the transmitter nor the receiver is used in this test. The signal from each coil should be uncorrelated (e.g., uncorrelated Gaussian noise). If two coils within the array have significantly correlated noise, the test system may output an inductive coupling warning.

More specifically, in one aspect of the present disclosure, DC switching supply 121 (FIG. 1) may supply power to DC switching supply 204 to energize all of the MRI coils 20 in the array, or all of the MRI coils in a particular segment or subset of the array. The signal from each coil should be Gaussian noise, uncorrelated to the noise produced by another coil in the array. If two coils within the array have significantly correlated noise (e.g., noise having a level of correlation above a threshold), the test system may output an inductive coupling warning (e.g., to warn a radiology technologist operating the MRI system).

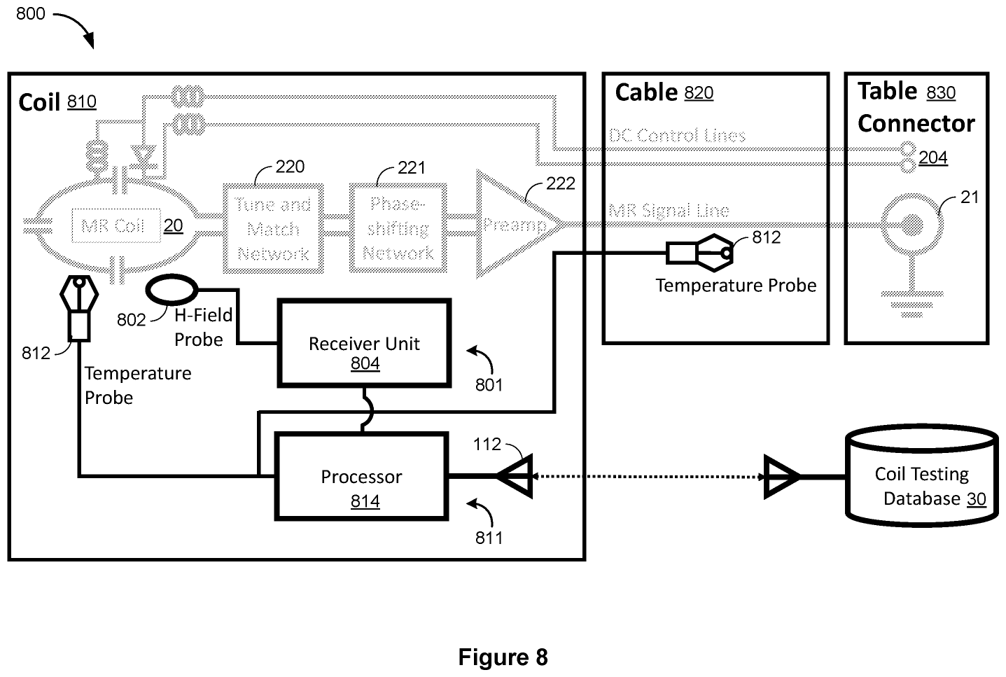

Turning now to FIG. 8, an alternative implementation of the testing system described above is depicted. While the implementations described above with reference to testing system 100 (FIGS. 1-7) involve an external testing system (including the transmit subsystem, receiver subsystem, and connector subsystem) that is designed to be operated separately from clinical use of the MRI system, the implementations described below with reference to testing system 800 (FIGS. 8-17) involve an integrated testing system that can be operated during clinical use of the MRI system.

The MRI coil 20, tune and match network 220, phase-shifting network 221, preamp 222, MRI signal line, DC control lines, and MR/RF connector 21 in testing system 800 correspond to those described above with reference to testing system 100, and are not further described here for purposes of brevity and so as no the descriptions above equally apply to the corresponding components in testing system 800.

However, in testing system 800, there are two main differences compared to testing system 100.

First, the receiver system probe 802 and receiver unit 804 in system 800 are embedded inside or otherwise internally coupled to the MRI coil 20 and may therefore make measurements during an MRI scan in a clinical setting. In contrast, the receiver antenna 110 and receiver unit 111 in system 100 may be coupled to an external testing fixture or jig for use outside the MRI scanner room prior to a scan. Since the probes and receiver unit in testing fixture 800 are inside (or otherwise integrated with or coupled to) the MRI coil, the transmit subsystem 10 (FIG. 1) is unnecessary and is therefore not part of system 800. Instead, the transmit signals described above with reference to system 100 may be applied internally by virtue of running the MRI system (e.g., by a controller and/or signal generator of the MRI system), and the receive signals described above with reference to system 100 are directly received from the MRI coil in system 800. Alternatively, rather than applying the transmit signals as described above with reference to system 100, the MRI coil circuitry 820 of system 800 may run normally (e.g., during clinical scans) while probe 802 senses and receiver unit 804 determines the natural resonant frequency of the coil 20.

Second, testing system 800 additionally includes temperature sensors 812 (e.g., fiber optic temperature sensors). The temperature sensors 812 (also referred to as temperature probes 812) are added to the MRI coil and/or the cable. This provides additional safety specifications, alerting the user if the coil is heating up to unsafe levels (e.g., past IEC regulatory standards).

System 800 is a complete safety test fixture that determines the health and safety of a receiver coil or array. System 800 includes a receiver subsystem 801 and a temperature subsystem 811.

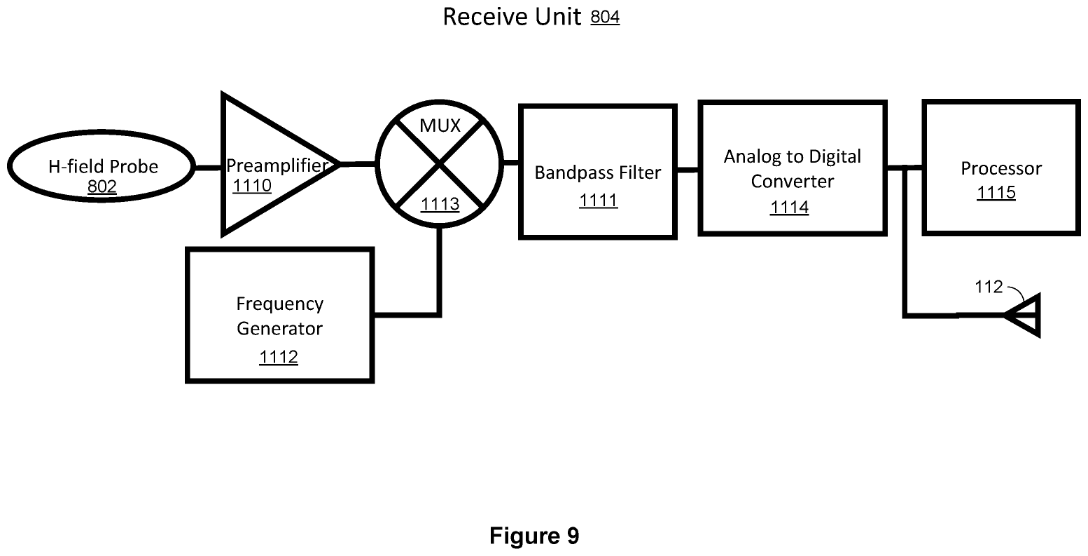

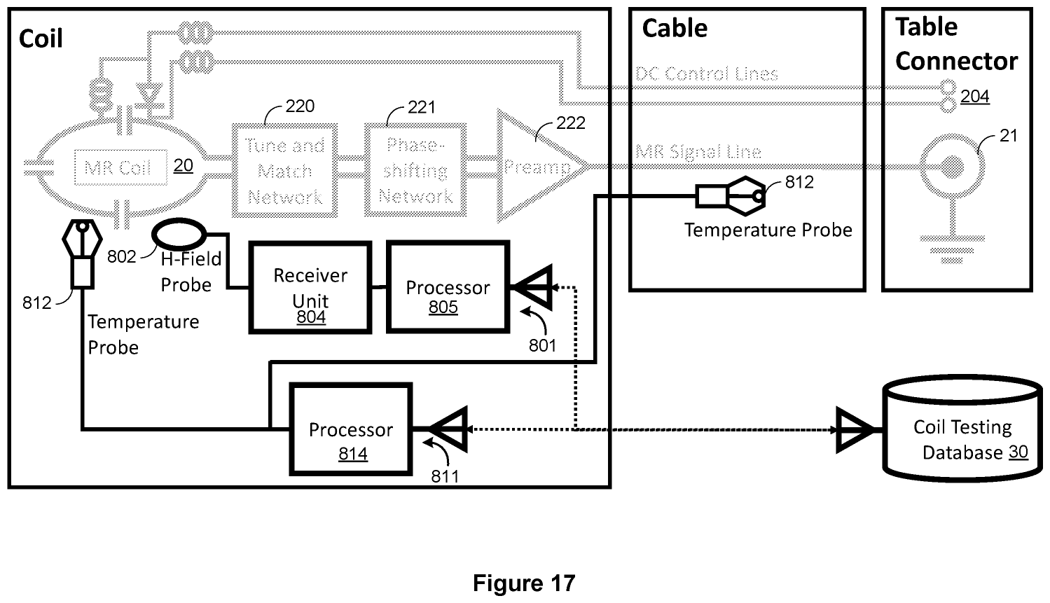

Receiver subsystem 801 in system 800 corresponds to receiver subsystem 11 in testing system 100. However, since receiver subsystem 801 in system 800 is located inside the MRI system and directly coupled to the coil, it may continuously monitor the coil or array throughout a patient scan. More specifically, receiver subsystem 801 includes a probe 802 (e.g., an H-field probe or the like), a receiver unit 804, and a processor (814 (FIG. 8), 1115 (FIG. 9), and/or 805 (FIG. 17)) (e.g., a microcontroller or microprocessor). Receiver subsystem 801 monitors the resonant (or Larmor) frequency as well as the ring-up and ring-down time (on and off time) for each individual coil within an array (similar to the receiver subsystem of system 100). If the coil's resonant frequency is too far from the known Larmor frequency, or if the ring-up or ring-down time is too long, the processor may output a warning (similar to the receiver subsystem of system 100).

FIG. 9 is a block diagram of the receive unit 804 of system 800 in accordance with some implementations. The components of the receive unit of system 800 correspond to respective components of the receive unit of system 100, and are not further described here for purposes of brevity. Receive unit 804 may include or otherwise be coupled to an antenna (Bluetooth or Wi-Fi) 112 to send the signal data to a cloud-based server 30 (FIG. 8) for more complex statistical algorithms (AI) to analyze the data to provide predictive trends for coil health (with respect to resonant.

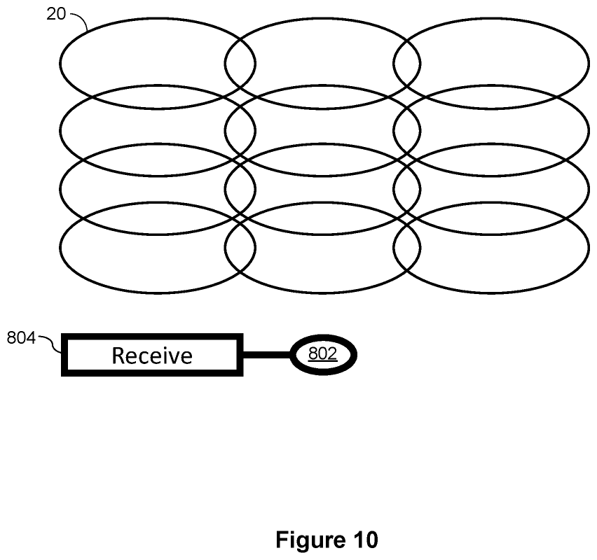

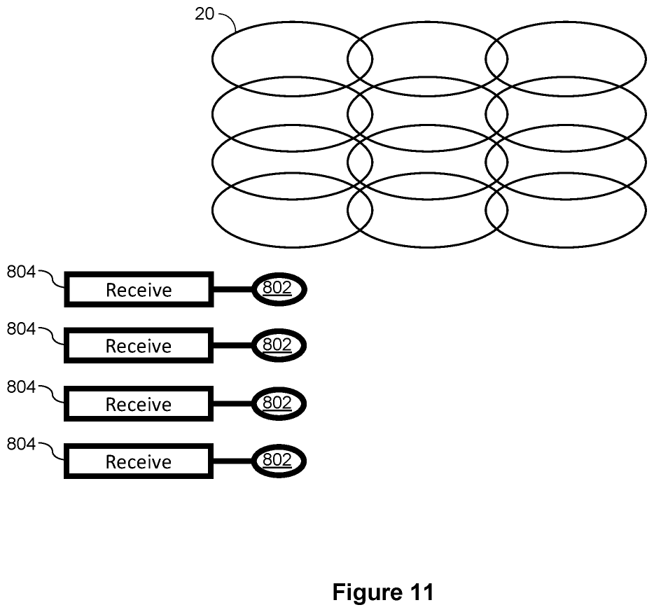

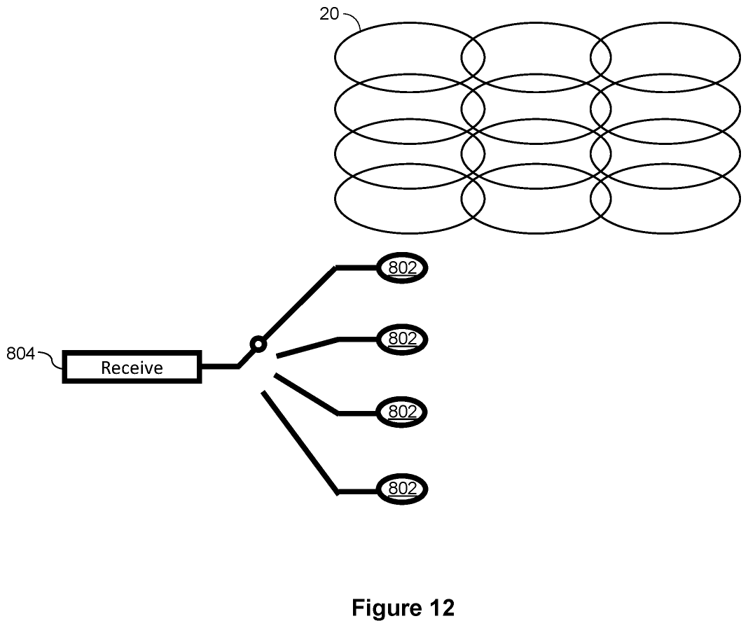

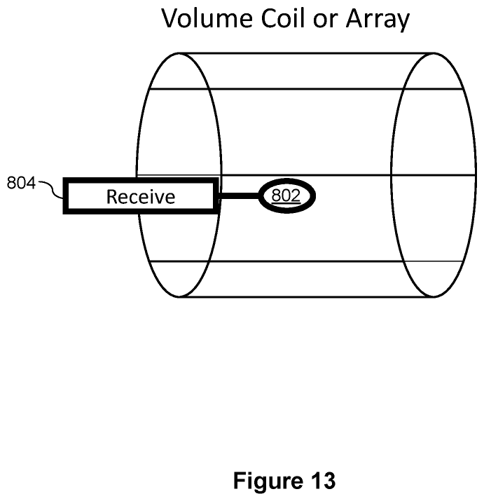

FIGS. 10-13 correspond to FIGS. 4-7, with the difference being lack of transmit subsystem in FIGS. 10-13 due to system 800 being integrated into the MRI system and not requiring an independent transmit subsystem as described with reference to system 100. Specifically, in system 800, a single receive subsystem (FIG. 10) or multiple receive subsystems (FIG. 11) may be used for an array of MRI coils, multiple H-field probes 802 (each corresponding to a different coil 20) may be switched to a single receive unit 804 (FIG. 12), and the coil array may be comprise planar coils (FIGS. 10-12) or volume coils (FIG. 13).

Referring back to FIG. 8, temperature subsystem 811 in system 800 includes a temperature probe 812 (e.g., any type of device that detects and measures hotness and coolness and converts it into an electrical signal) and a processor 814 configured to process the temperature data obtained from the temperature probes. Processor 814 may be the same processor as that used by the receiver subsystem (FIG. 8) or may be a separate processor (FIG. 17). Temperature subsystem 811 monitors the temperature of each individual coil 20 within the array and/or the temperature of the array cable 820 attached to the table mounted connector 830 of the MRI system. If the temperature of a coil 20 or the cable 820 is too high, processor 814 may output a warning.

More specifically, temperature subsystem 811 monitors the internal temperature of the individual coils 20 and cable assembly 820. If processor 814 determines that a monitored temperature exceeds a threshold (e.g., a threshold corresponding to a relevant standard, such as IEC 60601-1, IEC 60601-1-2, or an MITA standard), processor 814 may output a notification, notifying a user to end the current scan immediately. Processor 814 may output a subsequent notification, notify the user when the temperature is safe to scan again.

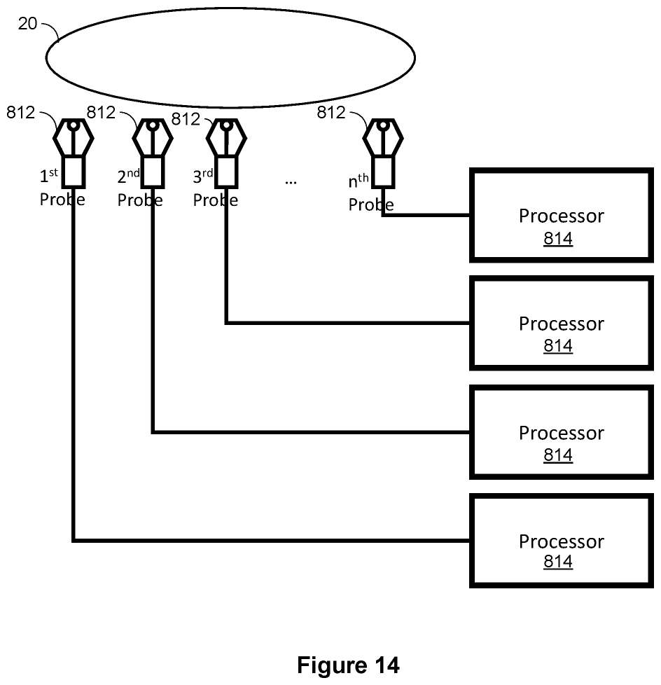

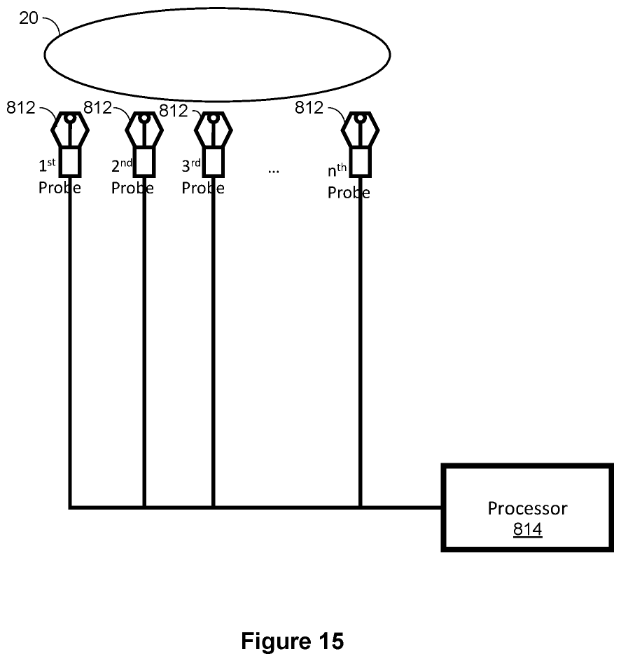

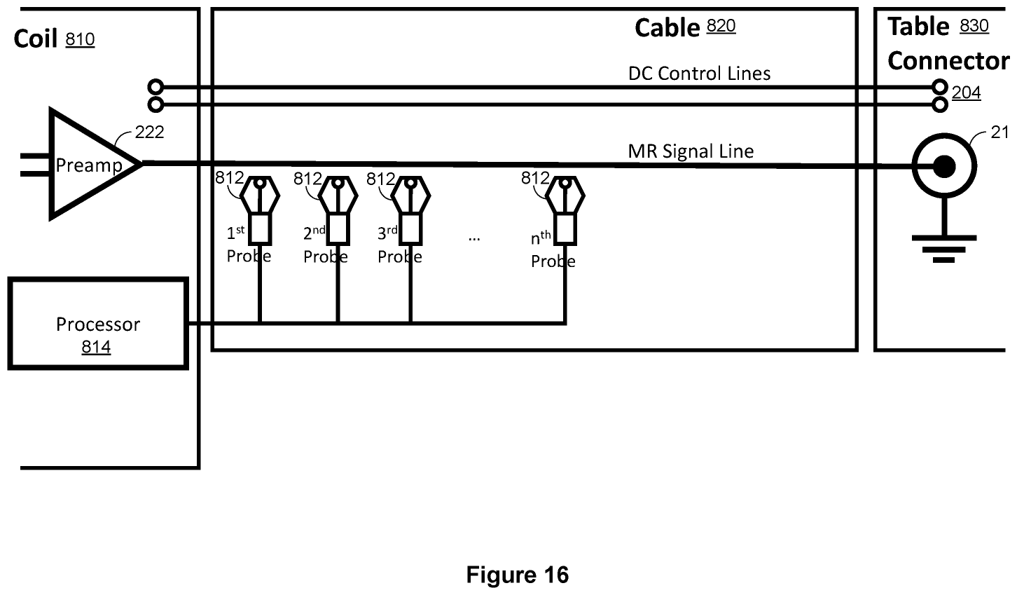

In some implementations, a temperature probe 812 (e.g., a fiber optic thermometer or thermal sensor) may be placed on or near each individual coil 20. Multiple temperature probes 812 may be placed on a single coil (as shown in FIGS. 14 and 15). Each temperature probe 812 may be coupled to a separate processor 814 (FIG. 14) or to the same processor 814 (FIG. 15). Additionally, multiple temperature probes 812 may be placed inside the cable 820 that is between the coil circuitry 810 and the table connector 830 (as shown in FIG. 16). The temperature probes 812 may be set at various intervals along the cable 820. The data from the temperature probes 812 is sent to processor(s) 814. Similar to the receive subsystem 801, the temperature subsystem 811 may be attached to an antenna 112 (Bluetooth or Wi-Fi) to send the temperature data to a cloud-based server 30 for more complex statistical algorithms (AI) to analyze the data to provide predictive trends for coil heating.

In conventional MRI systems, once a coil is cleared by the FDA for market, few temperature tests are performed on manufactured coils prior to entering the field. Additionally, conventional MRI systems have no method to monitor the temperature of the coils 20 or the temperature of the cable 820 in the clinical setting. Electrical safety regulatory standards, like IEC60601 and the MITA standards, have been set to keep patients safe. For example, to maintain compliance to the IEC standards, the temperature of the coils 20 must not exceed 43° C. Thus, with system 800, if the temperature probe 812 measures a temperature exceeding 43° C., processor 814 may immediately output a warning, notifying the user that temperature is unsafe and out of compliance with the standard. If temperature probe 812 detects temperatures nearing the threshold (e.g., between 41 and 43° C.) temperature subsystem 811 may continue to monitor the temperature (e.g., at a higher sample rate), and if temperature probe 812 continues to detect temperatures nearing the threshold for an extended amount of time, processor 814 may output an alert, notifying the user that the temperature is exceeding, or is close to exceeding, the standards and requesting that the user terminate the scan. Processor 814 may also output an alert notifying the user when the temperature is low enough to continue scanning.

The foregoing description, for the purpose of explanation, has been described with reference to specific implementations. However, the illustrative discussions above are not intended to be exhaustive or to limit the scope of the claims to the precise forms disclosed. Many modifications and variations are possible in view of the above teachings. The implementations are chosen in order to best explain the principles underlying the claims and their practical applications, to thereby enable others skilled in the art to best use the implementations with various modifications as are suited to the particular uses contemplated.

1. A testing system for testing a magnetic resonance imaging (MRI) coil, wherein the MRI coil is operatively coupled to an MRI system, the testing system comprising
a transmit subsystem, the transmit subsystem comprising a signal generator and a transmit antenna, wherein the signal generator is configured to generate a plurality of transmit signals at a plurality of transmit signal frequencies within a transmit frequency band including a Larmor Frequency, and wherein the transmit antenna is configured to transmit the plurality of transmit signals to the MRI coil;
a receiver subsystem, the receiver subsystem comprising a receiver unit and a receiver antenna, wherein the receiver antenna is configured to receive a plurality of frequency response signals from the MRI coil, wherein each one of the plurality of frequency response signals corresponds to one of the plurality of transmit signals, and wherein the receiver unit is configured to determine whether one of the plurality of frequency response signals with a highest amplitude corresponds to one of the plurality of transmit signals having the Larmor frequency, and output a notification if the highest amplitude does not correspond to one of the plurality of transmit signals having the Larmor frequency.

2. The testing system of claim 1, wherein the transmit antenna is coupled to the MRI coil, the receive antenna is coupled to the MRI coil, and the transmit antenna is inductively decoupled from the receive antenna.

3. The testing system of claim 1, further comprising an external antenna configured to transmit receive signal data, relating to the plurality of frequency response signals, to an MRI coil testing database.

4. The testing system of claim 3, wherein the MRI coil testing database is located in a remote location from the testing system.

5. The testing system of claim 4, wherein the MRI coil testing database is operatively coupled to an MRI coil testing server configured to perform statistical analysis on the receive signal data.

6. The testing system of claim 1, wherein the MRI system comprises a first MR/RF connector, the testing system further comprising a connector subsystem, the connector subsystem comprising a second MR/RF connector and a DC switching supply, wherein the second MR/RF connector is configured to be coupled to the first MR/RF connector, and wherein the DC switching supply is configured to provide power to the MRI coil for the test.

7. The testing system of claim 1, wherein the MRI system comprises a plurality of MRI coils.

8. The testing system of claim 7, wherein the transmit subsystem and the receiver subsystem are configured to test each of the plurality of MRI coils.

9. The testing system of claim 7, further comprising a plurality of transmit subsystems and a plurality of receiver subsystems, wherein each of the plurality of transmit subsystems and each of the plurality of receiver subsystems are coupled to a subset of the plurality of MRI coils.

10. The testing system of claim 7, comprising a plurality of transmit antennas and a plurality of receiver antennas;
wherein each of the plurality of transmit antennas and each of the plurality of receiver antennas are coupled to a subset of the plurality of MRI coils;
wherein the signal generator is configured to be operatively coupled to a first of the plurality of transmit antennas, at a first time;
wherein the receiver unit is configured to be operatively coupled to a first of the plurality of receive antennas at the first time;
wherein the signal generator is configured to be operatively coupled to a second of the plurality of transmit antennas at a second time; and
wherein the receiver unit is configured to be operatively coupled to a second of the plurality of receiver antennas at the second time.

11. A testing system for testing an MRI coil, wherein the MRI coil is operatively coupled to an MRI system, and wherein the MRI system further comprises a first magnetic resonance/radio frequency (MR/RF) connector and a detuning circuit coupled to the MR/RF connector, the testing system comprising:
a transmit subsystem, the transmit subsystem comprising a signal generator and a transmit antenna, wherein the signal generator is configured to generate a signal at a Larmor frequency, and wherein the transmit antenna is configured to transmit the signal to the MRI coil;
a connector subsystem comprising a second MR/RF connector and a DC switching supply, wherein the DC switching supply is coupled to the second MR/RF connector and the second MR/RF connector is configured to be coupled to the first MR/RF connector, and wherein the transmit subsystem is configured to transmit the signal at the Larmor frequency to the MRI coil while the connector subsystem activates a detuning circuit by switching direct current through the first MR/RF connector, for an amount of time sufficient to tune and detune the MRI coil; and
a receiver subsystem, the receiver subsystem comprising a receiver unit and a receiver antenna, wherein the receiver antenna is configured to receive a plurality of frequency response signals from the MRI coil in response to the signal at the Larmor frequency and the switching of the direct current, wherein the receiver unit is configured to measure amplitudes of the plurality of frequency response signals over time, determine a rate of rise and a rate of fall of the measured amplitudes, and output a notification if the rate of rise or the rate of fall does not meet a threshold.

12. The testing system of claim 11, wherein the detuning circuit comprises a PIN diode, and wherein the signal at the Larmor frequency is sent to the PIN diode.

13. The testing system of claim 11, wherein the detuning circuit comprises a MEMS switch, and wherein the signal at the Larmor frequency is sent to the MEMS switch.

14. The testing system of claim 11, further comprising an external antenna configured to transmit receive signal data, relating to the plurality of frequency response signals, to an MRI coil testing database.

15. The testing system of claim 14, wherein the MRI coil testing database is located in a remote location from the testing system.

16. The testing system of claim 15, wherein the MRI coil testing database is operatively coupled to an MRI coil testing server configured to perform statistical analysis on the receive signal data.

17. A testing system for testing an array of MRI coils, wherein the array is operatively coupled to an MRI system, the testing system comprising a receiver unit and a receiver antenna, wherein the receiver antenna is configured receive a plurality of noise signals from the array, and wherein the receiver unit is configured to measure whether a first of the plurality of noise signals from a first of the array of MRI coils is correlated to a second of the plurality of noise signals from a second of the array of MRI coils, and output a notification if the first of the plurality of noise signals is correlated to the second of the plurality of noise signals.

18. A testing system for testing a magnetic resonance imaging (MRI) coil, wherein the MRI coil is operatively coupled to an MRI system, the testing system comprising:
a signal generator configured to generate a plurality of transmit signals at a plurality of transmit signal frequencies within a transmit frequency band including a Larmor Frequency, and wherein the signal transmitter is configured to transmit the plurality of transmit signals to the MRI coil; and
a receiver subsystem, the receiver subsystem comprising a receiver unit and a receiver probe, wherein the receiver probe is configured to receive a plurality of frequency response signals from the MRI coil, wherein each one of the plurality of frequency response signals corresponds to one of the plurality of transmit signals, and wherein the receiver unit is configured to determine whether one of the plurality of frequency response signals with a highest amplitude corresponds to one of the plurality of transmit signals having the Larmor frequency, and output a notification if the highest amplitude does not correspond to one of the plurality of transmit signals having the Larmor frequency.

19. The testing system of claim 18, wherein the receiver probe is coupled to the MRI coil.

20. The testing system of claim 18, further comprising an external antenna configured to transmit receive signal data, relating to the plurality of frequency response signals, to an MRI coil testing database.

21. The testing system of claim 20, wherein the MRI coil testing database is located in a remote location from the testing system and is operatively coupled to an MRI coil testing server configured to perform statistical analysis on the receive signal data.

22. A testing system for testing an MRI coil, wherein the MRI coil is operatively coupled to an MRI system, and wherein the MRI system further comprises a detuning circuit, the testing system comprising:
a signal generator configured to generate a signal at a Larmor frequency and transmit the signal to the MRI coil;
a direct current (DC) switching supply coupled to circuitry of the MRI coil, wherein the signal generator is configured to transmit the signal at the Larmor frequency to the MRI coil while the DC switching supply activates a detuning circuit by switching direct current through the circuitry of the MRI coil, for an amount of time sufficient to tune and detune the MRI coil; and
a receiver subsystem, the receiver subsystem comprising a receiver unit and a receiver probe, wherein the receiver probe is configured to receive a plurality of frequency response signals from the MRI coil in response to the signal at the Larmor frequency and the switching of the direct current, wherein the receiver unit is configured to measure amplitudes of the plurality of frequency response signals over time, determine a rate of rise and a rate of fall of the measured amplitudes, and output a notification if the rate of rise or the rate of fall does not meet a threshold

23. The testing system of claim 22, wherein the detuning circuit comprises a PIN diode, and wherein the signal at the Larmor frequency is sent to the PIN diode.

24. The testing system of claim 22, wherein the detuning circuit comprises a MEMS switch, and wherein the signal at the Larmor frequency is sent to the MEMS switch.

25. The testing system of claim 22, further comprising an external antenna configured to transmit receive signal data, relating to the plurality of frequency response signals, to an MRI coil testing database.

26. The testing system of claim 25, wherein the MRI coil testing database is located in a remote location from the testing system and is operatively coupled to an MRI coil testing server configured to perform statistical analysis on the receive signal data.

27. A testing system for testing a magnetic resonance imaging (MRI) coil, wherein the MRI coil is operatively coupled to an MRI system, the testing system comprising:
a temperature subsystem configured to measure, during an MRI scan involving the MRI coil, a temperature of the MRI coil and a temperature of a cable coupling the MRI coil to a magnetic resonance/radio frequency (MR/RF) connector of the MRI system; and
a processor configured to determine whether the temperature of the MRI coil and/or the temperature of the cable exceeds a threshold, and output a notification if the temperature of the MRI coil and/or the temperature of the cable exceeds the threshold.

28. The testing system of claim 27, wherein the temperature subsystem includes a first plurality of temperature probes, each physically coupled to an MRI coil of an array of MRI coils of the MRI system, and a second plurality of temperature probes, each physically coupled to the cable.

29. The testing system of claim 27, further comprising an external antenna configured to transmit receive temperature data, relating to the temperature of the MRI coil and the temperature of the cable, to an MRI coil testing database.

30. The testing system of claim 29, wherein the MRI coil testing database is located in a remote location from the testing system and is operatively coupled to an MRI coil testing server configured to perform statistical analysis on the receive signal data.
